(19) United States
(12) Patent Application Publication
(10) Pub. No.: US 2025/0101145 A1
(43) Pub. Date: Mar. 27, 2025

(54) BLOCK COPOLYMERS AND METHODS OF MANUFACTURING INTEGRATED CIRCUIT DEVICES USING THE SAME

(71) Applicant: Samsung Electronics Co., Ltd., Suwon-si (KR)

(72) Inventors: Changhyeon An, Suwon-si (KR); Yeonsik Jung, Daejeon-si (KR); Yemin Park, Daejeon-si (KR); Jeehyun Hong, Daejeon-si (KR); Youngseog Kang, Suwon-si (KR); Changmin Park, Suwon-si (KR); Kwangsub Yoon, Suwon-si (KR); Jisun Lee, Suwon-si (KR)

(73) Assignee: Korea Advanced Institute of Science and Technology, Daejeon (KR)

(21) Appl. No.: 18/824,037

(22) Filed: Sep. 4, 2024

(30) Foreign Application Priority Data
Sep. 26, 2023 (KR) 10-2023-0129560

(51) Int. Cl. C08F 8/32; C08F 293/00; H01L 21/027; H01L 21/308

(52) U.S. Cl. CPC C08F 8/32; C08F 293/005; H01L 21/0273; H01L 21/3081; C08F 2400/02; C08F 2438/03

(57) ABSTRACT

A block copolymer is described, such as one including a first polymer block and a second polymer block that have different structures, wherein the first polymer block includes a first unit derived from an acrylic acid ester, and the second polymer block includes an inorganic material-containing random block, in which a second unit including an inorganic material-containing group and a third unit that is devoid of an inorganic material-containing group are connected to each other to provide a concentration gradient. Also described are methods of manufacturing an integrated circuit device that include forming, on a feature layer, a block copolymer layer including the block copolymer as set forth above; phase-separating the block copolymer layer to form a structure that includes a plurality of first domains that each include the first polymer block, and at least one second domain including the second polymer block; removing the plurality of first domains; and etching the feature layer using the at least one second domain as an etch mask.

### CROSS-REFERENCE TO RELATED APPLICATION

This application claims priority under 35 U.S.C. § 119 to Korean Patent Application No. 10-2023-0129560, filed on Sep. 26, 2023, in the Korean Intellectual Property Office, the disclosure of which is incorporated by reference herein in its entirety.

### FIELD

The present invention relates to a block copolymer and methods of manufacturing an integrated circuit device by using the same, and more particularly, to a block copolymer comprising a block, which comprises an inorganic material-containing group, and a method of manufacturing an integrated circuit device, the method comprising forming a pattern by using the block copolymer.

### BACKGROUND

Along with the increasing degree of integration of semiconductor devices, the areas occupied by unit cells in a plan view have been reduced. In response to such reduction in the areas of unit cells, the design rule of nano-scale critical dimensions (CDs), which are less than levels of several to tens of nm, has been applied to semiconductor synthesis. Thus, there is a desire for a new material and a new pattern formation method capable of improving line-edge roughness (LER), line-width roughness (LWR), and/or CD uniformity.

### SUMMARY

The present invention provides a block copolymer having a structure that is capable of facilitating vertical alignment due to simplified processes and improved phase separation properties when a plurality of fine patterns are repeatedly arranged and formed.

The present invention also provides a method of manufacturing an integrated circuit device, wherein the method is capable of forming fine patterns having improved line-edge roughness (LER), line-width roughness (LWR), and/or critical dimension (CD) uniformity. In some embodiments, the method of manufacturing provides excellent properties in phase separation and/or vertical alignment when a plurality of fine patterns are repeatedly arranged and formed.

According to an aspect of the present invention, there is provided a block copolymer comprising a first polymer block and a second polymer block that have different structures from each other, wherein the first polymer block comprises a first unit derived from an acrylic acid ester, and the second polymer block comprises a second unit, which comprises an inorganic material-containing group, and a third unit that is devoid of an inorganic material-containing group, and wherein the second polymer block comprises an inorganic material-containing random block having a concentration gradient. In the second polymer block, the second unit and the third unit are connected to each other and provide a concentration gradient.

According to another aspect of the present invention, there is provided a method of manufacturing an integrated circuit device, the method comprising forming, on a feature layer, a block copolymer layer comprising a block copolymer comprising a first polymer block and a second polymer block having different structures from each other, wherein the first polymer block comprises a first unit derived from an acrylic acid ester, and the second polymer block comprises a second unit, which comprises an inorganic material-containing group, and a third unit that is devoid of an inorganic material-containing group, and wherein the second polymer block comprises an inorganic material-containing random block having a concentration gradient and, in the second polymer block, the second unit and third unit are connected to each other to provide the concentration gradient, phase-separating the block copolymer layer to form a structure, wherein the structure comprises a plurality of first domains and at least one second domain that comprises the second polymer block, wherein each of the first domains of the plurality of first domains comprises the first polymer block; removing the plurality of first domains; and etching the feature layer by using the at least one second domain as an etch mask.

According to another aspect of the present invention, there is provided a method of manufacturing an integrated circuit device, the method comprising forming, on a feature layer, a block copolymer layer comprising a block copolymer, which includes a first polymer block and a second polymer block having different structures from each other, wherein the first polymer block comprises a first unit derived from an acrylic acid ester, the second polymer block comprises a second unit, which comprises a pendant group according to -M(R)₃, wherein M is a metalloid element or a metal element and R is a C1 to C10 linear or branched alkyl group, and a third unit that is devoid of an inorganic material-containing group, and wherein the second polymer block comprises an inorganic material-containing random block; phase-separating the block copolymer layer to form a structure, wherein the structure comprises a plurality of first domains and at least one second domain that comprises the second polymer block, wherein each of the first domains of the plurality of first domains comprises the first polymer block, and wherein the at least one second domain has a concentration gradient of the pendant group, which comprises the inorganic material, and the concentration gradient is over a distance extending from each of the plurality of first domains, removing the plurality of first domains; and etching the feature layer by using the at least one second domain as an etch mask.

### BRIEF DESCRIPTION OF THE DRAWINGS

Embodiments will be more clearly understood from the following detailed description taken in conjunction with the accompanying drawings in which:

FIG. 1 is a block diagram illustrating aspects of a structure of a block copolymer according to some embodiments;

FIG. 2 is a diagram schematically illustrating aspects of a block copolymer according to some embodiments;

FIGS. 3A and 3B are conceptual diagrams each illustrating aspects of a specific example of a structure of a block copolymer according to some embodiments;

FIG. 4 is a diagram illustrating aspects of an example of a synthesis process of a block copolymer according to some embodiments;

FIGS. 5A to 9B are diagrams illustrating aspects of a method of manufacturing an integrated circuit device, according to some embodiments; and, in particular, FIGS. 5A, 6A, 7A, 8A, and 9A are plan views illustrating aspects of a sequence of processes of the method of manufacturing an integrated circuit device; and FIGS. 5B, 6B, 7B, 8B, and 9B are cross-sectional views corresponding to the cross-sections taken along the line B-B′ in FIGS. 5A, 6A, 7A, 8A, and 9A, respectively;

FIG. 10A is a plan view illustrating aspects of an example of a self-assembled layer obtained from a block copolymer layer according to a method of manufacturing an integrated circuit device, according to some embodiments;

FIG. 10B is a cross-sectional view illustrating aspects of an example of a self-assembled layer obtained from a block copolymer layer according to a method of manufacturing an integrated circuit device, according to some embodiments;

FIG. 11A is a graph illustrating aspects of the surface energy of a comparative block copolymer depending on the surface energy and volume fraction of a specific polymer block in the comparative block copolymer, and FIGS. 11B, 11C, and 11D are graphs each illustrating aspects of the surface energy of a block copolymer according to the present invention depending on the surface energy and volume fraction of a specific polymer block in the block copolymer according to the present invention;

FIG. 12 illustrate aspects of a result of gel permeation chromatography of a block copolymer according to some embodiments;

FIG. 13 is a graph illustrating aspects of a hydrogen nuclear magnetic resonance spectrum of a block copolymer according to some embodiments, along with reaction time;

FIG. 14 is a graph illustrating aspects of a fraction of a monomer, pentafluorophenyl acrylate (PFPA), depending on a normalized polymer chain length in a block copolymer according to some embodiments;

FIGS. 15A and 15B are each graphs illustrating aspects of a nuclear magnetic resonance spectrum of a block copolymer according to some embodiments;

FIG. 16A is a scanning electron microscopic image illustrating aspects of a self-assembled layer obtained according to a method of manufacturing an integrated circuit device, according to some embodiments, FIG. 16B is a scanning electron microscopic image illustrating aspects of a self-assembled layer obtained according to a method of manufacturing an integrated circuit device, according to some embodiments, and FIG. 16C is a scanning electron microscopic image illustrating aspects of a self-assembled layer obtained according to a method of manufacturing an integrated circuit device, according to some embodiments;

FIG. 17 is a graph illustrating aspects of a result of grazing-incidence small-angle X-ray scattering (GI-SAXS) of a self-assembled layer obtained according to a method of manufacturing an integrated circuit device, according to some embodiments;

FIG. 18 is a graph illustrating aspects of a nuclear magnetic resonance spectrum of a block copolymer according to some embodiments; and

FIGS. 19 and 20 are each graphs illustrating aspects of a scanning electron microscopic image of a self-assembled layer obtained according to a method of manufacturing an integrated circuit device, according to some embodiments.

### DETAILED DESCRIPTION OF THE EMBODIMENTS

Hereinafter, embodiments of the present invention will be described in detail with reference to the accompanying drawings. Like components are denoted by like reference numerals throughout the specification, and repeated descriptions thereof are omitted.

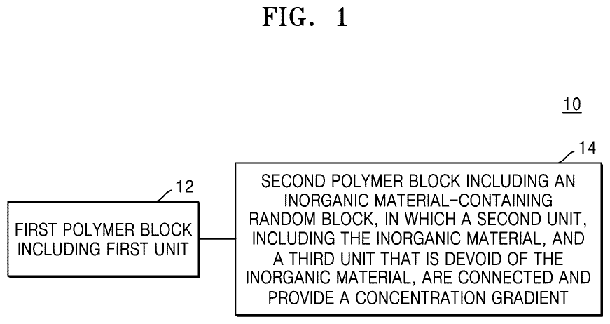

FIG. 1 is a block diagram illustrating aspects of a structure of a block copolymer according to some embodiments.

Referring to FIG. 1, a block copolymer 10 according to some embodiments comprises a first polymer block 12 and a second polymer block 14, wherein the first polymer block 12 and the second polymer block 14 have different structures from each other. The first polymer block 12 comprises a first unit derived from an acrylic acid ester, and the second polymer block 14 comprises a second unit, which comprises an inorganic material-containing group, and a third unit that is devoid of an inorganic material-containing group, wherein the second polymer block 14 comprises an inorganic material-containing random block and the second unit and the third unit are connected to each other to provide a concentration gradient.

In some embodiments, the inorganic material-containing group of the second unit comprises metalloid or a metal. In some embodiments, the inorganic material-containing group comprises one or more Si atoms or Sn atoms.

In some embodiments, in the second polymer block 14, the second unit comprises a pendant group have a structure according to -M(R)₃, wherein M is a metalloid element or a metal element and R is a C1 to C10 linear or branched alkyl group. As used herein, the term “C1 to C10 linear or branched alkyl group” refers to a linear or branched substituted or unsubstituted alkyl group having 1 to 10 carbon atoms. For example, the alkyl group may include, but is not limited to, a methyl, ethyl, n-propyl, isopropyl, n-butyl, isobutyl, sec-butyl, t-butyl, n-pentyl, n-hexyl, n-heptyl, or n-octyl group. As used herein, the term “substituted” is meant to indicate that a hydrogen atom of a compound is substituted by a substituent selected from a halogen atom, a hydroxyl group, a nitro group, a cyano group, an amino group, a thiol group, or any combination thereof. The halogen atom may include F, Cl, Br, or I.

In some embodiments, the first unit of the first polymer block 12 comprises an acrylic acid ester repeating unit, such as methyl acrylate, ethyl acrylate, propyl acrylate, n-butyl acrylate, t-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, or propyltrimethoxysilane acrylate. In some embodiments, the first polymer block 12 comprises a methacrylic acid ester repeating unit, such as methyl methacrylate, ethyl methacrylate, propyl methacrylate, n-butyl methacrylate, t-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, or propyltrimethoxysilane methacrylate.

In some embodiments, the second unit of the second polymer block 14 comprises an acrylic acid ester repeating unit or a methacrylic acid ester repeating unit and has a structure that include an inorganic material-containing group. In some embodiments, the inorganic material-containing group comprises a pendant group having a structure according to -M(R)₃, wherein M and R are the same as defined above.

In some embodiments, the third unit of the second polymer block 14 comprises a repeating unit of substituted or unsubstituted styrene or a derivative thereof. For example, the third unit may comprise one repeating unit selected from styrene substituted with one or more halogen atoms, α-methylstyrene substituted with one or more halogen atoms, 2-methylstyrene substituted with one or more halogen atoms, 3-methylstyrene substituted with one or more halogen atoms, 4-methylstyrene substituted with one or more halogen atoms, 4-t-butylstyrene, 4-n-octylstyrene substituted with one or more halogen atoms, 2,4,6-trimethylstyrene substituted with one or more halogen atoms, 4-methoxystyrene substituted with one or more halogen atoms, 4-t-butoxystyrene, 4-hydroxystyrene substituted with one or more halogen atoms, 4-nitrostyrene substituted with one or more halogen atoms, 3-nitrostyrene substituted with one or more halogen atoms, 4-chlorostyrene substituted with one or more halogen atoms, 4-fluorostyrene substituted with one or more halogen atoms, 4-acetoxyvinylstyrene substituted with one or more halogen atoms, 4-vinylbenzyl chloride substituted with one or more halogen atoms, 1-vinylnaphthalene substituted with one or more halogen atoms, 4-vinylbiphenyl substituted with one or more halogen atoms, 1-vinyl-2-pyrrolidone substituted with one or more halogen atoms, 9-vinylanthracene substituted with one or more halogen atoms, and vinylpyridine substituted with one or more halogen atoms.

In some embodiments, in the block copolymer 10 according to some embodiments, the first unit of the first polymer block 12 comprises poly(methyl methacrylate) (PMMA), the second unit of the second polymer block 14 comprises an acrylate substituted by the inorganic material-containing group, and the third unit of the second polymer block 14 comprises polystyrene (PS).

In some embodiments, the block copolymer 10 according to some embodiments comprises a structure according to General Formula 1.

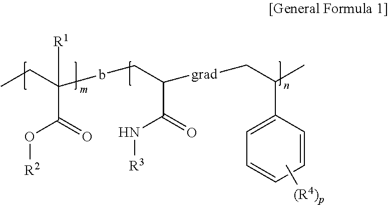

In General Formula 1,
R¹ is a hydrogen atom or a methyl group;
R² is a hydrogen atom, a C1 to C10 linear or branched alkyl group, or a C1 to C10 linear or branched alkyl halide group;
R³ is a pendant group comprising an inorganic atom;
each R⁴ is independently a hydrogen atom, a halogen atom, a C1 to C5 linear or branched alkyl group, or a C1 to C5 linear or branched alkyl halide group;
p is an integer of 1 to 5; and
m/(m+n) and n/(m+n) are each 0.2 to 0.8.

In General Formula 1, the term “grad” is an abbreviation of gradient and means that the composition of the random block copolymer has a concentration gradient (e.g., is a gradient copolymer). The term “concentration gradient” as used herein refers to a change in the concentration of one or more units of the polymer from one portion (e.g., one end or region) of the polymer to another portion (e.g., another end or region) of the polymer, optionally in a direction extending along the polymer backbone of the polymer. In some embodiments, the concentration gradient may be selected from a range of about 0 to about 1. Average concentration fractions in the second polymer block 14 of the block copolymer 10 may vary.

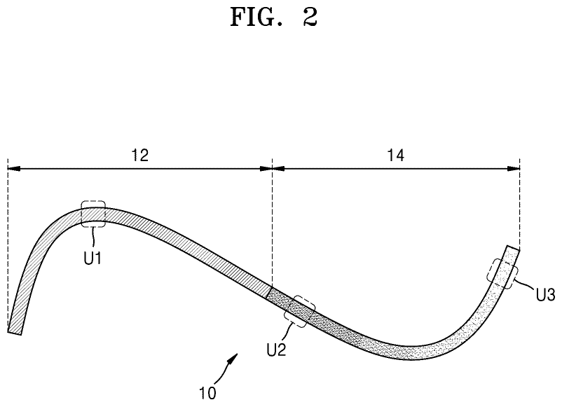

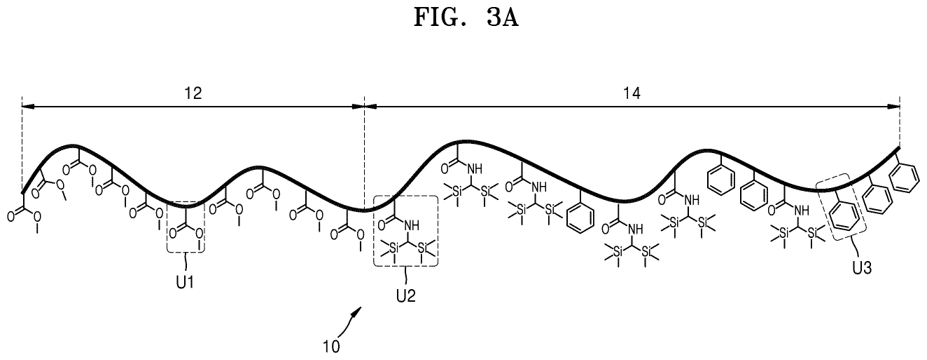

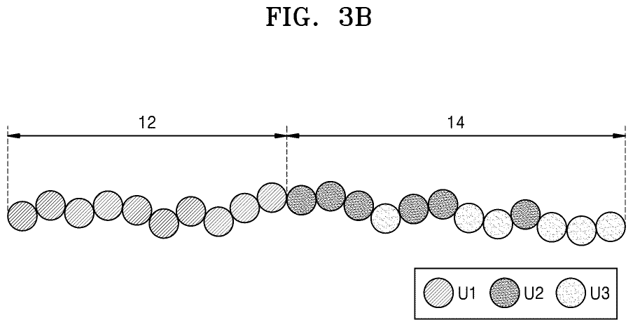

FIG. 2 is a diagram schematically illustrating aspects of the block copolymer 10 shown in FIG. 1. FIGS. 3A and 3B are conceptual diagrams each illustrating aspects of a specific example of the structure of the block copolymer 10.

Referring to FIGS. 2, 3A, and 3B, the block copolymer 10 according to some embodiments comprises a first polymer block 12 and a second polymer block 14, which are connected to each other. In some embodiments, the first polymer block 12 comprises a plurality of first units U1, and the second polymer block 14 comprises a plurality of second units U2 and a plurality of third units U3. At a first region in the second polymer block 14 that is close to the first polymer block 12, the first region comprises an amount of (e.g., a number of) the second units U2 that is greater than the amount of (e.g., a number of) the third unit U3, and at a second region in the second polymer block 14 that is relatively far from the first polymer block 12, the amount of the second units U2 in the second region may be less (e.g., fewer) than the amount of the third units U3 in the second region.

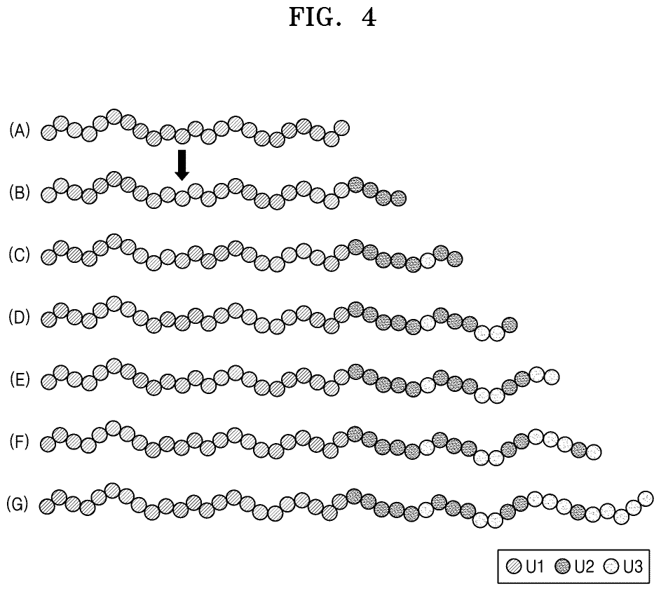

FIG. 4 is a diagram illustrating aspects of an example of a synthesis process of the block copolymer 10 described with reference to FIGS. 1, 2, 3A, and 3B.

Referring to FIG. 4, as schematically shown in (A) of FIG. 4, according to some embodiments a homopolymer comprising a plurality of first units U1 may be used as a macroinitiator for the synthesis of the block copolymer 10. Next, according to some embodiments, as schematically shown in the order of (B), (C), (D), (E), (F), and (G) in FIG. 4 starting from (B), the plurality of second units U2 and the plurality of third units U3 may be polymerized from one end of the plurality of first units U1. Here, according to some embodiments, in the initial stage of the polymerization (e.g., at a position close to the homopolymer comprising the plurality of first units U1), the second unit U2 is prone to be polymerized (e.g., included in the polymer) more than the third unit U3. By comparison, according to some embodiments, the third unit U3 is prone to be polymerized (e.g., included in the polymer) more than the second unit U2 at positions further away from the homopolymer comprising the plurality of first units U1.

In some embodiments, the block copolymer 10 according to some embodiments comprises a structure according to Formula 1 (e.g., poly(methyl methacrylate)-block-poly(bis(trimethylsilyl)methylamido acrylate-gradient-styrene)).

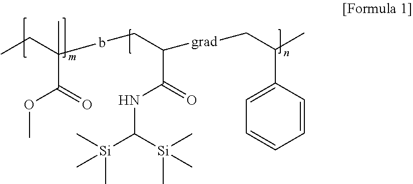

### Poly(methyl methacrylate)-block-poly(bis(trimethylsilyl)methylamido acrylate-gradient-styrene)

In some embodiments, the block copolymer of Formula 1 comprises a first polymer block, which comprises a polymethyl methacrylate repeating unit; and a second polymer block comprising a concentration gradient block, which comprises a poly(bis(trimethylsilyl)methylamido acrylate) polymer unit and a styrene polymer unit. in some embodiments, the poly(bis(trimethylsilyl)methylamido acrylate) polymer unit comprises silicon atoms in an amount of about 24.5 wt %, that is, a relatively high amount, based on the molecular weight of the poly(bis(trimethylsilyl)methylamido acrylate) polymer unit. In some embodiments, in the block copolymer according to Formula 1, the amount of silicon atoms in the second polymer block may be adjusted by controlling the magnitudes of the concentration gradients of the poly(bis(trimethylsilyl)methylamido acrylate) polymer unit and the styrene polymer unit and the degrees of polymerization thereof, as needed (e.g., by increasing the number of poly(bis(trimethylsilyl)methylamido acrylate) polymer units in the portion of the second polymer block adjacent to the first polymer block).

In some embodiment, the block copolymer 10 according to some embodiments comprises a structure according to Formula 2 (e.g., Poly(methylmethacrylate)-block-poly(3-((tributylstannyl)methoxy)-1-propanacetamide)-gradient-styrene)).

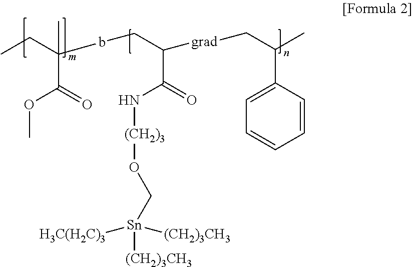

### Poly(methylmethacrylate)-block-poly(3-((tributylstannyl)methoxy)-1-propanacetamide)-gradient-styrene)

In some embodiments, the block copolymer of Formula 2 comprises a first polymer block, which comprises a polymethyl methacrylate repeating unit; and a second polymer block comprising a concentration gradient block, which comprises a poly(3-((tributylstannyl)methoxy)-1-propaneacetamide) polymer unit and a styrene polymer unit. In some embodiments, the poly(3-((tributylstannyl)methoxy)-1-propaneacetamide) polymer unit comprises one or more tin atoms in an amount of about 27.5 wt %, that is, a relatively high amount, based on the molecular weight of the poly(3-((tributylstannyl)methoxy)-1-propaneacetamide) polymer unit. In some embodiments, in the block copolymer of Formula 2, the amount of tin atoms in the second polymer block may be easily adjusted by controlling the magnitudes of the concentration gradients of the poly(bis(trimethylsilyl)methylamido acrylate) polymer unit and the styrene polymer unit and the degrees of polymerization thereof, as needed (e.g., by increasing the number of poly(bis(trimethylsilyl)methylamido acrylate) polymer units in the portion of the second polymer block adjacent to the first polymer block).

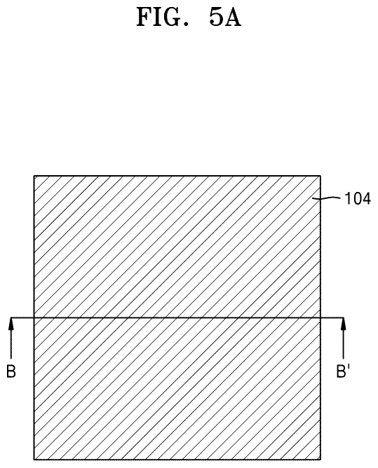

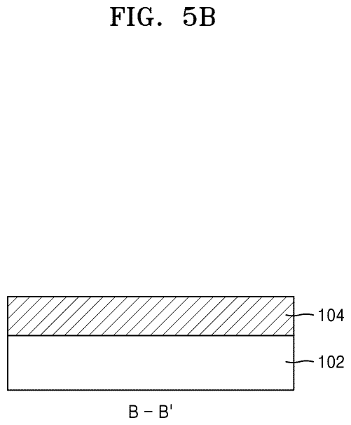

FIGS. 5A to 9B are diagrams illustrating aspects of a method of manufacturing an integrated circuit device, according to some embodiments, and in particular, FIGS. 5A, 6A, 7A, 8A, and 9A are plan views respectively illustrating aspects of a sequence of processes of the method of manufacturing an integrated circuit device, and FIGS. 5B, 6B, 7B, 8B, and 9B are cross-sectional views corresponding to the cross-sections taken along the line B-B′ in FIGS. 5A, 6A, 7A, 8A, and 9A, respectively.

Referring to FIGS. 5A and 5B, according to some embodiments a feature layer 104 may be formed on a substrate 102.

In some embodiments, the substrate 102 may comprise a semiconductor substrate. In some embodiments, the substrate 102 may comprise a semiconductor material, such as Si or Ge. In some embodiments, the substrate 102 may comprise a compound semiconductor material, such as SiGe, SiC, GaAs, InAs, or InP. In some embodiments, the substrate 102 may comprise a silicon-on-insulator (SOI) structure. In some embodiments, the substrate 102 may comprise a conductive region, for example, an impurity-doped well or an impurity-doped structure. In some embodiments, the substrate 102 may comprise various device isolation structures, such as a shallow trench isolation (STI) structure.

In some embodiments, the feature layer 104 may comprise an inorganic insulating film or an inorganic conductive film. For example, the feature layer 104 may include, but is not limited to, a metal, an alloy, a metal carbide, a metal nitride, a metal oxynitride, a metal oxycarbide, a semiconductor material, polysilicon, an oxide, a nitride, an oxynitride, a hydrocarbon compound, or any combination thereof.

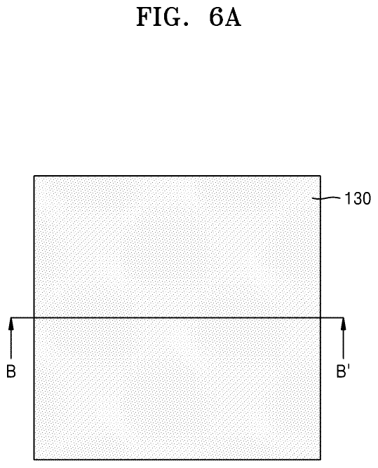

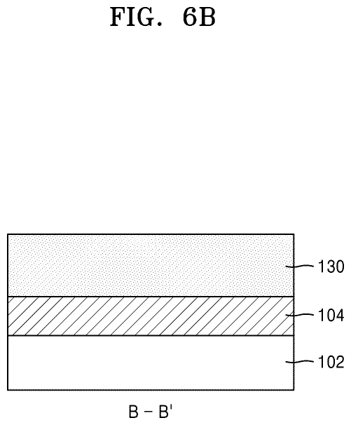

Referring to FIGS. 6A and 6B, according to some embodiments a block copolymer layer 130 may be formed on the feature layer 104. In some embodiments, the block copolymer layer 130 may comprise the block copolymer 10 as described with reference to FIG. 1.

In some embodiments, the block copolymer layer 130 may comprise the block copolymer 10 as described with reference to FIGS. 1, 2, 3A, and 3B. In some embodiments, the block copolymer layer 130 may comprise a structure of the block copolymer having the structure as described with reference to General Formula 1, Formula 1, or Formula 2, or a structure selected from the block copolymers having various structures modified and changed therefrom without departing from the scope of the present invention. In some embodiments, the block copolymer comprising the block copolymer layer 130 may have, but is not limited to, a molecular weight of about 20 kg/mol to about 100 kg/mol.

In some embodiments, to form the block copolymer layer 130, one block copolymer selected from among the block copolymers according to some embodiments may be dissolved in an organic solvent; and then an obtained solution may be coated on the feature layer 104 by a dip coating, solution casting, or spin coating process. In some embodiments, the organic solvent may include, but is not limited to, propylene glycol monomethyl ether acetate (PGMEA), propylene glycol monomethyl ether (PGME), ethyl-3-ethoxy propionate (EEP), ethyl lactate (EL), 2-hydroxyisobutyric acid methyl ester (HBM), gamma-butyrolactone (GBL), toluene, and/or tetrahydrofuran (THF).

According to the present invention, the block copolymer layer 130 may be formed to directly contact the surface of the feature layer 104 and, before the block copolymer layer 130 is formed, a surface treatment, such as the formation of a neutral brush liner, is not performed on an exposed surface of the feature layer 104.

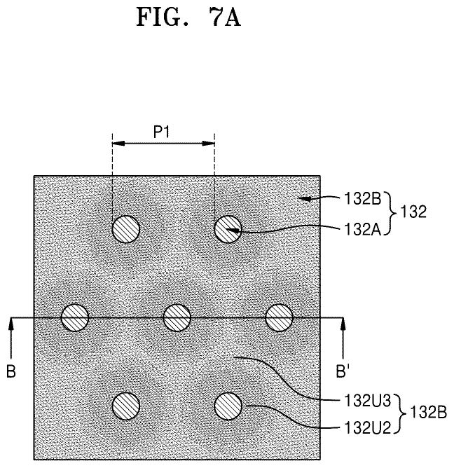

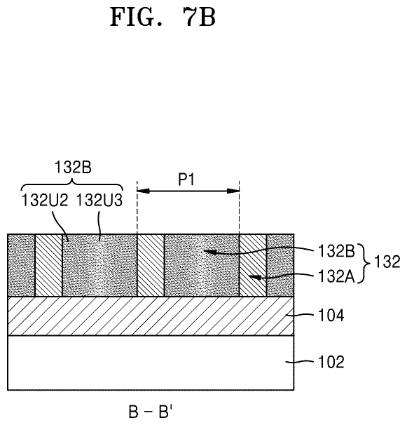

Referring to FIGS. 7A and 7B, according to some embodiments in the resulting product of FIGS. 6A and 6B, the block copolymer layer 130 may undergo phase separation, thereby forming a self-assembled layer 132. In some embodiments, the self-assembled layer 132 comprises a plurality of first domains 132A, wherein each first domain of the plurality of first domains comprises a first polymer block; and a second domain 132B comprising a second polymer block.

In some embodiments, in the self-assembled layer 132, the first polymer block, which is included in each of the plurality of first domains 132A, may have the same configuration as the first polymer block 12 as described with reference to FIGS. 1 and 2.

In some embodiments, in the self-assembled layer 132, the second domain 132B may be formed to surround the plurality of first domains 132A. In some embodiments, the second domain 132B comprises an inorganic material-containing pendant group. In some embodiments, the second domain 132B may have a concentration gradient of the inorganic material-containing pendant group, wherein the concentration gradient depends on the distance from each of the plurality of first domains 132A. For example, in the second domain 132B of the self-assembled layer 132, the amount of the inorganic material-containing pendant group increases with decreasing distance from each of the plurality of first domains 132A, and the amount of the inorganic material-containing pendant group decreases with increasing distance from each of the plurality of first domains 132A.

In some embodiments, the second polymer block of the second domain 132B may have the same configuration as the second polymer block 14 as described with reference to FIGS. 1 and 2. That is, similar to the second polymer block 14 described with reference to FIGS. 1 and 2, the second polymer block of the second domain 132B may comprise a plurality of second units U2 and a plurality of third units U3. In some embodiments, in the self-assembled layer 132, the second polymer block of the second domain 132B may comprise a second unit-dominant region 132U2, which is adjacent to each of the plurality of first domains 132A, and a third unit-dominant region 132U3, which is apart from (e.g., not adjacent to) each of the plurality of first domains 132A with the second unit-dominant region 132U2 therebetween (e.g., the plurality of first domains 132A is surrounded by a copolymer gradient, wherein the copolymer gradient comprises a domain region 132U2 that is adjacent to the plurality of first domains 132A and has a higher number of second units; and a domain region 132U3 that is then adjacent to the domain region 132U2, but not adjacent to the plurality of first domains 132A and has a higher number of third units). In some embodiments, the amount of the second unit U2 (see FIG. 2, 3A, or 3B) of the second domain 132 in the second unit-dominant region 132U2, which is adjacent to the first domain 132A, may be greater than the amount of the second unit U2 (see FIG. 2, 3A, or 3B) of the second domain 132B in the third unit-dominant region 132U3 (e.g., the second unit-dominant region 132U2 comprises a higher number of the second unit U2 than are in the third unit-dominant region 132U3). In addition, in some embodiments, the amount of the third unit U3 (see FIG. 1) of the second domain 132B in the third unit-dominant region 132U3 may be greater than the amount of the third unit U3 (see FIG. 1) in the second unit-dominant region 132U2 (e.g., the second unit-dominant region 132U2 comprises a fewer number of the third unit U3 than are in the third unit-dominant region 132U3).

As described in some embodiments with reference to FIGS. 7A and 7B, to perform the phase separation on the block copolymer layer 130, the block copolymer layer 130 may be annealed at a temperature that is higher than the glass transition temperature (Tg) of the block copolymer in the block copolymer layer 130. For example, to perform the phase separation on the block copolymer layer 130, the block copolymer layer 130 may be annealed at a temperature selected from a range of about 130° C. to about 300° C. for about 15 minutes to about 24 hours.

In some embodiments, the vertical alignment properties of the first domain 132A may improve after the block copolymer layer 130 is phase-separated on the feature layer 104. In some embodiments, the vertical alignment properties may improve even when there is no surface treatment means, such as a neutral brush liner, between the block copolymer layer 130 and the feature layer 104. In some embodiments, the plurality of first domains 132A may be regularly arranged. For example, the plurality of first domains 132A may be arranged to form hexagonal arrays arranged with a first pitch P1.

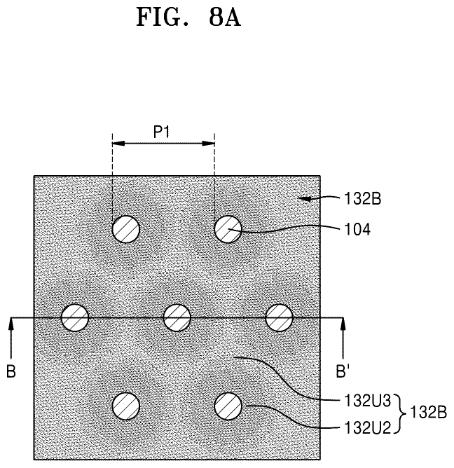

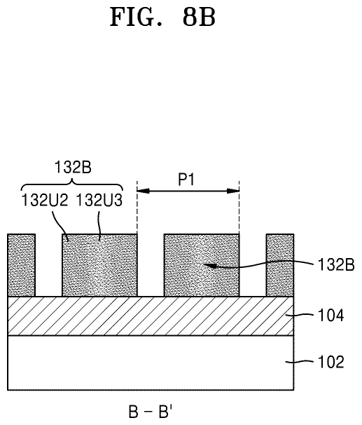

Referring to FIGS. 8A and 8B, according to some embodiments in the resulting product of FIGS. 7A and 7B, the plurality of first domains 132A may be removed from the self-assembled layer 132.

In some embodiments, to selectively remove only the plurality of first domains 132A from the self-assembled layer 132, a process may be performed in which the plurality of first domains 132A are selectively decomposed by applying a polymer decomposer to the self-assembled layer 132, and then stripping the plurality of decomposed first domains 132A using a cleaning solution, for example, isopropyl alcohol (IPA). In some embodiments, radiant rays or plasma may be used as the polymer decomposer. In some embodiments, the radiant rays may be provided in an oxygen atmosphere. In some embodiments, the radiant rays comprise deep ultraviolet (DUV) light, soft X-rays, or electron beams (E-beams). In some embodiments, the plasma comprises oxygen plasma. To selectively decompose the plurality of first domains 132A, the type or energy of the polymer decomposer may be selected. For example, the second domain 132B and each of the plurality of first domains 132A may respectively have different threshold energies allowing the decomposition thereof to start. Therefore, radiant rays or plasma having energy capable of selectively decomposing only the plurality of first domains 132A, from among the plurality of first domains 132A and the second domain 132B, may be applied to the self-assembled layer 132. In some embodiments, the radiant energy or plasma energy may be adjusted by radiant-ray irradiation time or plasma exposure time.

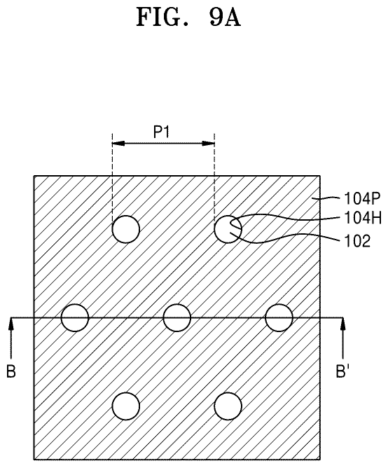

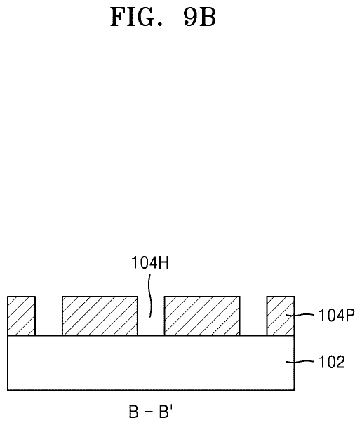

Referring to FIGS. 9A and 9B, according to some embodiments in the resulting product of FIGS. 8A and 8B, the feature layer 104 may be etched by using the second domain 132B as an etch mask, thereby forming a pattern 104P in which a plurality of holes 104H are formed. Next, the second domain 132B remaining on the pattern 104P may be removed.

In some embodiments, the plurality of holes 104H, which are formed in the pattern 104P, may be arranged to form hexagonal arrays arranged with a first pitch P1.

According to the manufacturing method of an integrated circuit device of the present invention, which is described with reference to FIGS. 5A to 9B, in the self-assembled layer 132 obtained by the phase separation of the block copolymer layer 130, the plurality of first domains 132A and the second domain 132B may each be vertically aligned even without using a separate surface energy neutralization process, such as a neutral brush liner. Using a manufacturing method of the present invention, the phase separation properties of the block copolymer layer 130 may improve. In addition, because the second domain 132B used as an etch mask comprises an inorganic material, when the feature layer 104 is etched by using the second domain 132B as an etch mask, the second domain 132B may have excellent etch resistance (e.g., the second domain 132B comprising an inorganic material has a high etch resistance). Therefore, when the pattern 104P comprising the plurality of holes 104H is formed by using the self-assembled layer 132, the line-edge roughness (LER), line-width roughness (LWR), and/or critical dimension (CD) uniformity of the pattern 104P may improve.

In the manufacturing method of an integrated circuit device, which is described with reference to FIGS. 5A to 9B, although descriptions have been made by taking an example, in which, among the plurality of first domains 132A and the second domain 132B each vertically aligned in the self-assembled layer 132 obtained by the phase separation of the block copolymer layer 130 as described with reference to FIGS. 7A and 7B, each of the plurality of first domains 132A has an approximately cylindrical shape, and in which the plurality of first domains 132A are removed as described with reference to FIGS. 8A and 8B and the pattern 104P including the plurality of holes 104H formed therein is formed by etching the feature layer 104 by using the second domain 132B as an etch mask as described with reference to FIGS. 9A and 9B, the inventive concepts are not limited thereto.

For example, unlike the example shown in FIGS. 7A and 7B, in some embodiments the conditions of the phase separation of the block copolymer layer 130 may be variously controlled, thereby forming a self-assembled layer comprising the first domain 132A and the second domain 132B, which each have various planar shapes.

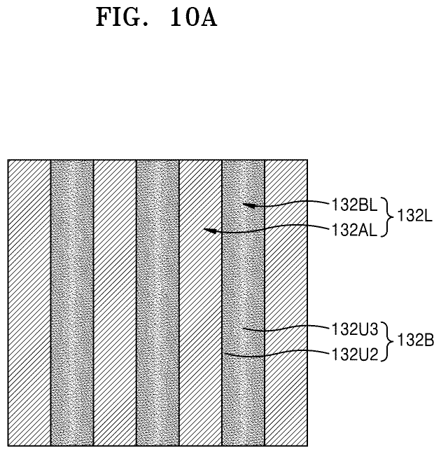

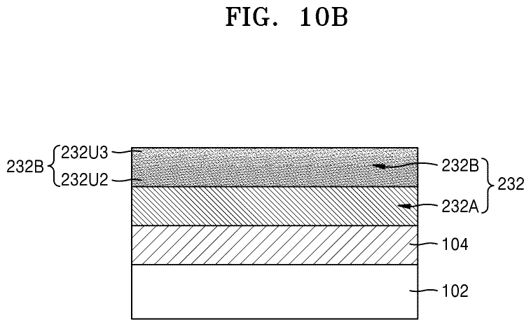

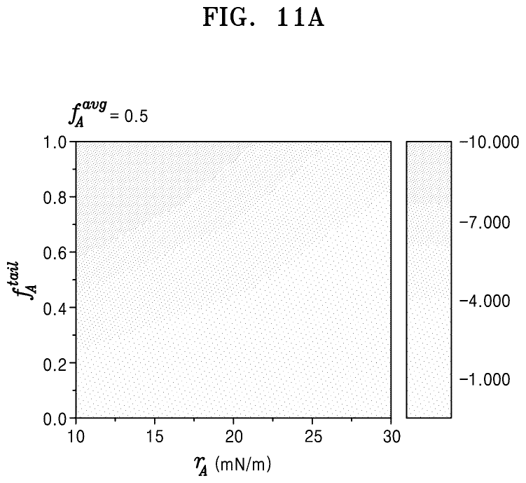

FIG. 10A is a plan view illustrating an example of a self-assembled layer 132L, which is self-assembled through the vertical alignment performed such that the block copolymer layer 130 (see FIGS. 6A and 6B) undergoes phase separation in a similar manner to that described with reference to FIGS. 7A and 7B but has a different planar shape from the planar shape shown in FIGS. 7A and 7B.

Referring to FIG. 10A, while a phase separation process of the block copolymer layer 130 is performed in a similar manner to that described with reference to FIGS. 7A and 7B by using one of block copolymers according to some embodiments, the self-assembled layer 132L obtained through the phase separation of the block copolymer layer 130 may include a plurality of first domains 132AL and a plurality of second domains 132BL, which respectively have line-type planar shapes extending parallel to each other in the horizontal direction and are vertically aligned to be alternately arranged one-by-one. Further, each of the plurality of second domains 132BL may comprise a second unit-dominant region 132U2 and a third unit-dominant region 132U3. More detailed configurations of the second unit-dominant region 132U2 and the third unit-dominant region 132U3 are the same as described above with reference to FIGS. 7A and 7B. Self-assembly conditions well known in the art may be used to form the self-assembled layer 132L comprising the plurality of first domains 132AL and the plurality of second domains 132BL, which each have a line-type planar shape.

In some embodiments, in the process described above with reference to FIGS. 7A and 7B, a phase separation atmosphere of the block copolymer layer 130 may be used and controlled as needed so as to form a plurality of domains that are horizontally aligned.

FIG. 10B is a cross-sectional view illustrating aspects of an example of forming a self-assembled layer 232 comprising a first domain 232A and a second domain 232B, which are horizontally aligned through the phase separation of the block copolymer layer 130 (see FIGS. 6A and 6B). In FIG. 10B, the same reference numerals as in FIGS. 5A to 9B respectively denote the same members, and here, repeated descriptions thereof are omitted.

The first domain 232A may have a similar configuration to that of the first domain 132A described with reference to FIGS. 7A and 7B. The second domain 232B may have a concentration gradient of an inorganic material-containing pendant group depending on the distance from the first domain 232A. For example, in the second domain 232B of the self-assembled layer 232, the amount of the inorganic material-containing pendant group may increase toward the first domain 232A and may decrease away from the first domain 232A (e.g., the number of inorganic material-containing pendant groups in the polymer of the second domain 232B may be higher in regions adjacent to the first domain 232A).

In some embodiments of the self-assembled layer 232, the first domain 232A comprises a first polymer block, which has the same configuration as the first polymer block 12 described with reference to FIGS. 1 and 2. In some embodiments of the self-assembled layer 232, the second domain 232B comprises a second polymer block, which has a substantially similar configuration to that of the second polymer block 14 described with reference to FIGS. 1 and 2. That is, similar to the second polymer block 14 described with reference to FIGS. 1 and 2, the second polymer block of the second domain 232B may include a plurality of second units U2 and a plurality of third units U3. In the self-assembled layer 232, the second polymer block of the second domain 232B may include a second unit-dominant region 232U2, which is adjacent to the first domain 232A, and a third unit-dominant region 232U3, which is apart from the first domain 232A with the second unit-dominant region 232U2 therebetween. The amount of the second unit U2 (see FIG. 1) of the second domain 232B in the second unit-dominant region 232U2, which is located adjacent to the first domain 232A, may be greater than the amount of the second unit U2 (see FIG. 1) of the second domain 232B in the third unit-dominant region 232U3. In addition, the amount of the third unit U3 (see FIG. 1) of the second domain 232B in the third unit-dominant region 232U3 may be greater than the amount of the third unit U3 (see FIG. 1) in the second unit-dominant region 232U2. In the self-assembled layer 232, the second domain 232B may constitute the uppermost layer that is in contact with air.

In the directed self-assembly (DSA) technique of a block copolymer according to some embodiments, a pattern is formed by using a molecular-level self-assembly phenomenon due to the thermodynamic immiscibility of blocks that are included in the block copolymer. The DSA technique may be applied to a next-generation exposure process and used to form a mask for an ultrafine pattern by a simple process.

To transfer a pattern with high quality according to some embodiments, a high-quality mask having high performance needs to be formed by the DSA technique. As described with reference to FIGS. 1 and 2, in the block copolymer 10 according to some embodiments, the second polymer block 14 comprises an inorganic material-containing random block, in which a second unit comprising an inorganic material-containing group and a third unit that is devoid of an inorganic material-containing substituent are connected to each other to have concentration gradients. In some embodiments, the second polymer block 14 comprising an inorganic material-containing group may provide excellent etch resistance when used as an etch mask. In addition, in some embodiments, the second polymer block 14 comprising an inorganic material-containing group has a relatively high value of a Flory-Huggins interaction parameter (x). Therefore, the block copolymer 10 may be phase-separated relatively well even when the degree of polymerization thereof is reduced, thereby providing a better effect in forming a fine pattern.

As a comparative example, a PS-b-PDMS (polystyrene-block-poly(dimethylsiloxane)) block copolymer has a structure comprising silicon atoms in a polymer backbone and comprises silicon in an extremely high amount of about 37 wt %. While a PS-b-PDMS polymer has a relatively high value of x, it is difficult for the PS-b-PDMS polymer to form lamellae due to relatively low self-assembly kinetics thereof, and because a repeating unit in which an inorganic material is included in a polymer backbone (e.g., PDMS), has extremely low surface energy, a self-assembly guide surface thereof is required to undergo neutral polymer brush treatment to form a vertically aligned pattern. In addition, in some embodiments, an additional organic synthesis reaction is required for the polymer set forth above to form a block copolymer with a general organic polymer because anionic polymerization, ring-opening polymerization, condensation polymerization, or the like, has relatively difficult polymerization conditions when used for a polymer comprising an inorganic material in the backbone thereof.

So far, it has been difficult to synthesize a block copolymer which comprises an inorganic material and has a structure allowing an intended pattern to be formed due to a high value of x and a high self-assembly rate thereof and allowing the block copolymer to be used as an etch mask having high etch resistance. Therefore, the inventors of the present invention have developed a block copolymer satisfying the above conditions and a synthesis method thereof, to improve the quality of a pattern intended to be formed in a pattern formation process that uses a photolithography process.

As described above with reference to FIGS. 1 and 2, the block copolymer 10 according to some embodiments comprises a first polymer block 12 and a second polymer block 14, which respectively have different structures. Here, the first polymer block 12 comprises a first unit derived from an acrylic acid ester, and the second polymer block 14 comprises an organic material-containing random block, in which a second unit comprising an inorganic material-containing group and a third unit that is devoid of an inorganic material-containing substituent are connected to each other to provide a concentration gradient, wherein the second unit comprising the inorganic material-containing group as a pendant group is connected to a polymer backbone rather than in the polymer backbone. The block copolymer 10 according to some embodiments may allow the amount of the second unit, which comprises an inorganic material-containing group, to be adjusted by using a reactive polymer during a synthesis process of the block copolymer 10 and may have a structure in which the second unit and the third unit are arranged to have a concentration gradient.

In some embodiments, a block copolymer synthesized by using a reactive polymer may be modified by another material. In general, it is difficult to synthesize a block copolymer comprising an inorganic material-containing group in a polymer backbone without any particular organic reaction. However, after a block copolymer is polymerized, when an inorganic reactant is used in the process of modifying the block copolymer, a block copolymer including an inorganic material-containing group as a pendant group may be synthesized. The block copolymer 10, which is obtained through a synthesis process as such, according to some embodiments may significantly improve the applicability of a polymer comprising an inorganic material and may form various block copolymers together with various organic polymers having various structures.

So far, it has been known that, to form a vertically aligned phase by using a structure of a block copolymer having a high value of x, a process of neutralizing energy of a surface, on which the block copolymer is self-assembled, is essential because there is a great difference in energy between two blocks. That is, block copolymers known so far have been able to form aligned phases with desired shapes only on specific surfaces having equal or similar affinity with respect to each of a plurality of monomer units, for example, two monomer units, which are included in each of the block copolymers. Unlike the block copolymers known so far, in the block copolymer 10 according to some embodiments, the second unit constituting the second polymer block 14 may comprise a monomer unit comprising an inorganic material-containing group as a pendant group and having relatively low surface energy, and the third unit constituting the second polymer block 14 may comprise a styrene monomer unit comprising no inorganic material-containing pendant group and having relatively high surface energy. In addition, in the second polymer block 14, the second unit and the third unit may be arranged to have concentration gradients (e.g., to be a gradient copolymer). Therefore, the block copolymer 10 according to some embodiments comprises a block copolymer comprising a polymer, which comprises an inorganic material having low surface energy, and may be vertically aligned without separate surface treatment, unlike other block copolymers known so far.

To synthesize the block copolymer 10 according to some embodiments, a block copolymer comprising a reactive polymer may be synthesized first by reversible addition fragmentation chain transfer (RAFT) polymerization. The block copolymer comprising the reactive polymer may comprise a first block comprising an organic polymer and a second block comprising a random polymer, which has concentration gradients of the reactive polymer and the organic polymer. In some embodiments, the random polymer having the concentration gradients may be synthesized by using the difference in reactivity with which monomers are synthesized. After the block copolymer comprising the reactive polymer is polymerized, a block copolymer comprising a block, which has a concentration gradient of a polymer comprising an inorganic material, may be synthesized by a modification reaction. For example, by reacting the block copolymer comprising the reactive polymer with an inorganic reactant, a block copolymer comprising a block, which has a concentration gradient of a polymer comprising an inorganic material, may be synthesized.

In general, because a block copolymer, which comprises a polymer comprising an inorganic material, is synthesized by an anionic polymerization method that uses an n-butyl lithium initiator, such a block copolymer has drawbacks in that process control is difficult due to the high reactivity thereof and a lot of costs (e.g., due to reagent usage) are consumed in processes. On the other hand, according to the present invention, because a RAFT polymerization method can be used to synthesize the block copolymer 10, the block copolymer 10 may be synthesized in a small amount or a large amount without the fine adjustment of temperature or humidity and reaction environments.

In addition, according to the present invention, to synthesize the block copolymer 10, a reactive polymer is polymerized and then converted into a polymer comprising an inorganic material through a modification. Therefore, according to the present invention, the amount of an inorganic material in a block comprising the inorganic material may be adjusted depending on the ratio between a reactive monomer and another monomer having a different structure from the reactive monomer. During this process, a block copolymer may be synthesized to include a polymer comprising a pendant group, which comprises various types of materials, for example, an organic material, an inorganic material, or a combination thereof, depending on the type of a selected reactant.

Because the block copolymer 10 according to some embodiments comprises the second polymer block 14 comprising inorganic material-containing random blocks that are connected to each other to have an inorganic material concentration gradient, the block copolymer 10 may have a relatively high value of x and allow a self-assembled pattern of a polymer to be vertically aligned through a coating process and an annealing process without a surface energy neutralization layer and/or a top coat. Therefore, because the block copolymer 10 according to some embodiments may undergo vertical alignment by self-assembly through a relatively simple process, the block copolymer 10 may be effectively used as an etch mask in a pattern formation process using a photolithography process. In addition, when the block copolymer 10 according to some embodiments comprises a metal as the inorganic material, a domain comprising the second polymer block 14, in a self-assembled structure obtained by the phase separation of the block copolymer 10, may provide better etch resistance.

In the block copolymer 10 according to some embodiments, the inorganic material may be present in a relatively high amount of at least 20 wt %. As a comparative example, the amount of silicon atoms in a PS-b-PDMS block copolymer may be at an approximately similar level of the amount of the inorganic material in the block copolymer 10 according to some embodiments. However, unlike the comparative example, the block copolymer 10 according to some embodiments may be vertically aligned even without brush treatment for surface neutralization.

Next, an example of a method of designing the second polymer block 14, which comprises an inorganic material-containing random block having an inorganic material concentration gradient, in the block copolymer 10 according to some embodiments.

The following descriptions are made by comparing, as a comparative example, a block copolymer (hereinafter, referred to as a comparative block copolymer) comprising a random block without any inorganic concentration gradient with a block copolymer (hereinafter, referred to as a block copolymer of the present invention) comprising an inorganic material-containing random block having an inorganic material concentration gradient as in the block copolymer 10 (e.g., a gradient copolymer) according to some embodiments.

In some embodiments, self-aligned structures of each of the comparative block copolymer and the block copolymer of the present invention may be divided into three structures, that is, a vertically aligned lamellar structure (Vertical structure) and two horizontally aligned lamellar structures (Horizontal_1 structure and Horizontal_2 structure). For example, it may be assumed that the comparative block copolymer has a structure of PMMA-b-P(A-random-S) and the block copolymer of the present invention has a structure of PMMA-b-P(A-gradient-S) comprising a concentration gradient random block (e.g., gradient copolymer block). Here, the Vertical structure refers to the case where PMMA and P(A-random-S) are each vertically aligned in the self-aligned structure of the comparative block copolymer and the case where PMMA and P(A-gradient-S) are each vertically aligned in the self-aligned structure of the block copolymer of the present invention. The Horizontal_1 structure refers to the case where PMMA and P(A-random-S) are each horizontally aligned and P(A-random-S) constitutes the uppermost layer, which contacts air, in the self-aligned structure of the comparative block copolymer and the case where PMMA and P(A-gradient-S) are each horizontally aligned and P(A-gradient-S) constitutes the uppermost layer, which contacts air, in the self-aligned structure of the block copolymer of the present invention. The Horizontal_2 structure refers to the case where PMMA and P(A-random-S) are each horizontally aligned and PMMA constitutes the uppermost layer, which contacts air, in the self-aligned structure of the comparative block copolymer and the case where PMMA and P(A-gradient-S) are each horizontally aligned and PMMA constitutes the uppermost layer, which contacts air, in the self-aligned structure of the block copolymer of the present invention. Here, each of the comparative block copolymers, that is, PMMA-b-P(A-random-S), and the block copolymers of the present invention, that is, PMMA-b-P(A-gradient-S), may be aligned in a structure having the lowest surface energy at a surface thereof contacting air. That is, the three self-aligned structures may each be determined by surface energy (γ^{air}) at the surface contacting air. For a stable self-aligned structure, the surface energy at the surface contacting air needs to be minimized. Therefore, a polymer may be aligned in a structure having the lowest surface energy from among the three structures.

Table 1 shows the surface energy of PMMA-b-P(A-random-S) in each of the Vertical structure, the Horizontal_1 structure, and the Horizontal_2 structure.

TABLE 1

| γₐᵢᵣ^{ver} | γₐᵢᵣ^{hor}_1 | γₐᵢᵣ^{hor}_2 |
|---|---|---|
| $\frac{{γ}_{PMMA} + \{ {γ}_{P S} ( 1 - {f}_{A} ) + {γ}_{A} {f}_{A} )}{2}$ | γ_{PS}(1 − f_{A}) + γ_{A}f_{A} | γ_{PMMA} |

Table 2 shows the surface energy of PMMA-b-P(A-gradient-S) in each of the Vertical structure, the Horizontal_1 structure, and the Horizontal_2 structure.

TABLE 2

| γₐᵢᵣ^{ver} | γₐᵢᵣ^{hor}_1 | γₐᵢᵣ^{hor}_2 |
|---|---|---|
| $\frac{{γ}_{PMMA} + \{ {γ}_{P S} ( 1 - {f}_{A}^{a v g} ) + {γ}_{A} {f}_{A}^{a v g} )}{2}$ | γ_{PS}(1 − f_{A}^{tail}) + γ_{A}f_{A}^{tail} | γ_{PMMA} |

In Tables 1 and 2,
γₐᵢᵣ^{ver}=Surface energy of Vertical structure,
γₐᵢᵣ^{hor_1}=Surface energy of Horizontal_1 structure,
γₐᵢᵣ^{hor_2}=Surface energy of Horizontal_2 structure,
f_{A}=Volume fraction of A monomer in P(A-random-S) block (f_{A}=f_{A}^{tail}=f_{A}^{avg}),
f_{A}^{avg}=Average volume fraction of A monomer in P(A-gradient-S) block, and
f_{A}^{tail}=Volume fraction of A monomer at one end of P(A-gradient-S) block, wherein the one end refers to an end, which is not connected with PMMA, out of both ends of the P(A-gradient-S) block.

When the block copolymer 10 according to some embodiments is used to transfer a pattern in a photolithography process, it may be better that the block copolymer 10 has properties of forming vertically aligned patterns. Therefore, the block copolymer 10 may be designed such that a vertically aligned polymer structure has the lowest surface energy, through the polymer design. In some embodiments, a design function of a polymer may comprise the surface energy (γ_{A}) intrinsic to the A block and the volume fraction (f_{A}, f_{A}^{avg}, or f_{A}^{tail}) of the A monomer in the P(A-gradient-S) block, which is a block having a concentration gradient (e.g., a gradient copolymer block). In the P(A-random-S) block, which is a random block, the surface energy may be influenced by the average volume fraction (f_{A}=f_{A}^{tail}=f_{A}^{avg}) of the A monomer, and in the P(A-gradient-S), which is a concentration gradient block (e.g., a gradient copolymer block), the surface energy may be influenced by the average volume fraction (f_{A}^{avg}) of the A monomer in the P(A-gradient-S) block and by the volume fraction (f_{A}^{tail}) of the A monomer at an end of the P(A-gradient-S) block.

For the vertical alignment to be preferred, γ^{air}_{vertical}, which is the surface energy of a vertically aligned structure, needs to be minimum. This may be represented by Inequality 1.

$$Δ {γ}_{air} = {γ}_{air}^{hor} - {γ}_{air}^{ver} \geq 0 \qquad [ Inequality 1 ]$$

Inequality 1 indicates that the surface energy of a horizontally aligned structure is greater than the surface energy of a vertically aligned structure, and thus, the vertically aligned structure is more stable. Therefore, the block copolymer 10 according to some embodiments satisfies the condition of Δγ^{air}>0 and thus may be designed to make the vertical alignment more stable.

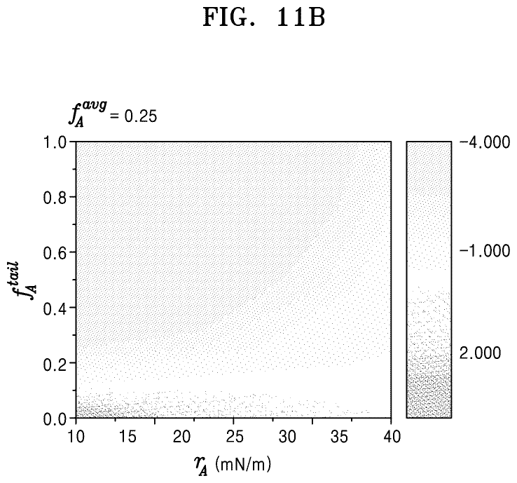

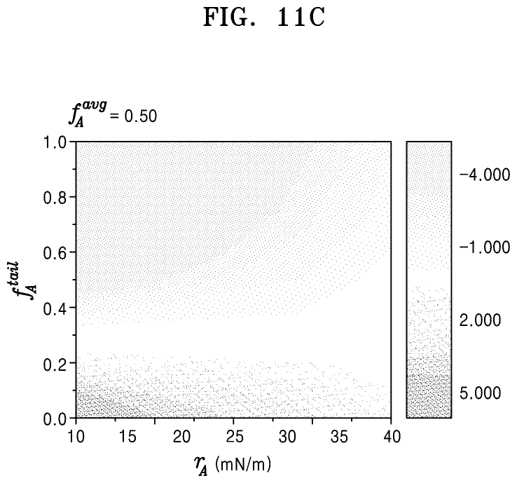

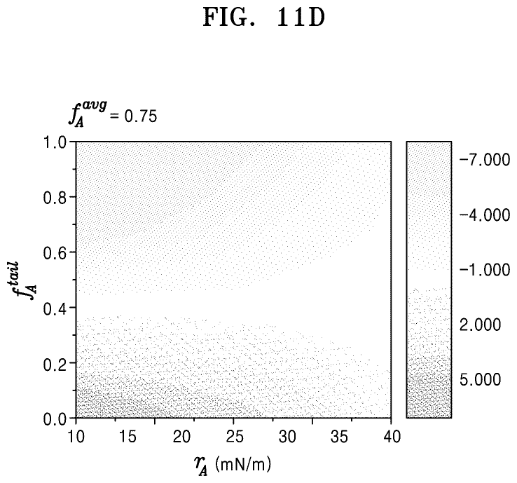

FIG. 11A is a graph illustrating aspects of the surface energy of PMMA-b-P(A-random-S), which is the comparative block copolymer, depending on the surface energy and volume fraction of the A block, and FIGS. 11B, 11C, and 11D are graphs each illustrating aspects of the surface energy of PMMA-b-P(A-gradient-S), which is the block copolymer of the present invention, depending on the surface energy and volume fraction of the A block.

In FIG. 11A, the X-axis represents the surface energy (γ_{A}) intrinsic to the A block and the Y-axis represents the volume fraction (f_{A}) of the A monomer in the P(A-random-S) block. In FIGS. 11B to 11D, the X-axis represents the surface energy (γ_{A}) intrinsic to the A block and the Y-axis represents the volume fraction (f_{A}) of the A monomer in the P(A-gradient-S) block. As in FIGS. 11A to 11D, assuming that the surface energy (γ_{A}) intrinsic to the A block is on the X-axis and the volume fraction (f_{A}) of the A monomer in the P(A-gradient-S) block or the P(A-gradient-S) block is on the Y-axis, Δγ^{air} may be calculated by using the values shown in Tables 1 and 2.

In FIGS. 11A to 11D, the case where the vertical alignment is preferred due to the satisfaction of the condition of Δγ^{air}>0 is indicated by dark gray, and the case where the horizontal alignment is preferred due to the satisfaction of the condition of Δγ^{air}<0 is indicated by light gray.

In some embodiments, to form a block copolymer to be vertically aligned, each of the surface energy (γ_{A}) intrinsic to the A block and the volume fraction (f_{A}) of the A monomer in the P(A-gradient-S) block is required to have a value in the range indicated by dark gray in FIGS. 11B to 11D. As in FIG. 11A, in the case of a block copolymer comprising the P(A-random-S) block, which is a random block, the horizontal alignment is preferred throughout the entire ranges in which evaluation is performed. On the other hand, as in FIGS. 11B to 11D, in the case of the P(A-gradient-S) block, it may be seen that the vertical alignment is preferred at particular surface energy and a particular volume fraction, and thus, that there is a range indicated by dark gray. That is, in the P(A-gradient-S) block, it may be seen that, when the surface energy (γ_{A}) intrinsic to the A block is low and the volume fraction (f_{A}^{tail}) of the A monomer is low at an end of the P(A-gradient-S) block, the vertical alignment is preferred. The block copolymer 10 may be designed based on such evaluation results, thereby forming a vertically aligned pattern.

Next, an example of a method of synthesizing a block copolymer according to some embodiments is described.

### Synthesis Example 1

### Synthesis of poly(methyl methacrylate)-block-poly(pentafluorophenyl acrylate-gradient-styrene)

A synthesis process of poly(methyl methacrylate)-block-poly(pentafluorophenyl acrylate-gradient-styrene) is briefly shown in Reaction Formulae 1 and 2.

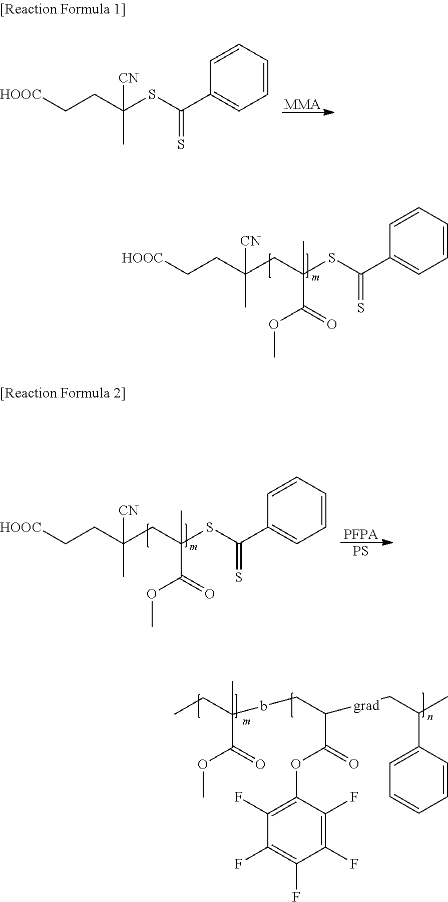

More specifically, azobisisobutyronitrile (AIBN), a RAFT reagent (4-cyano-4-(phenylcarbonothioylthio) pentanoic acid (CPCPA)), and methyl methacrylate (MMA) were dissolved with a molar ratio of 2:1:10000 in benzene, followed by reacting obtained reactants at 80° C. for 1 hour while injecting nitrogen thereto, thereby polymerizing a PMMA polymer. The polymerization of a polymer of pentafluorophenyl acylate (PFPA) and a polymer of styrene was performed by using the obtained PMMA polymer as a macroinitiator. The macroinitiator, AIBN, PFPA, and styrene were dissolved with a molar ratio of 0.2:1:250:120 in anisole and underwent freezing-pumping-unfreezing processes, followed by performing polymerization at 70° C. for 6 hours in a vacuum atmosphere, thereby obtaining poly(methyl methacrylate)-block-poly(pentafluorophenyl acrylate-gradient-styrene) that is a block copolymer (number-average molecular weight: 32155, molecular weight distribution: 1.23). The mole fractions of the respective repeating units in the obtained block copolymer were checked by hydrogen nuclear magnetic resonance spectroscopy.

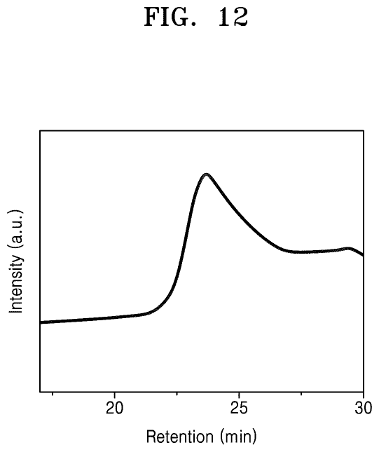

FIG. 12 is a graph illustrating aspects of a result of gel permeation chromatography of the block copolymer obtained in Synthesis Example 1. Because there is one peak in FIG. 12, it may be confirmed that a polymer with a single molecular weight was synthesized.

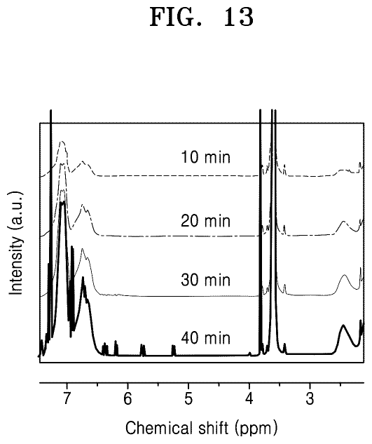

FIG. 13 is a graph illustrating aspects of a hydrogen nuclear magnetic resonance spectrum of the block copolymer obtained in Synthesis Example 1, depending on the reaction time thereof. By measuring the hydrogen nuclear magnetic resonance spectrum of the polymer for each reaction time based on the result of FIG. 13, the volume fraction (f_{PFPA}) of a reactive monomer, PFPA, in the synthesized polymer for each reaction time may be calculated.

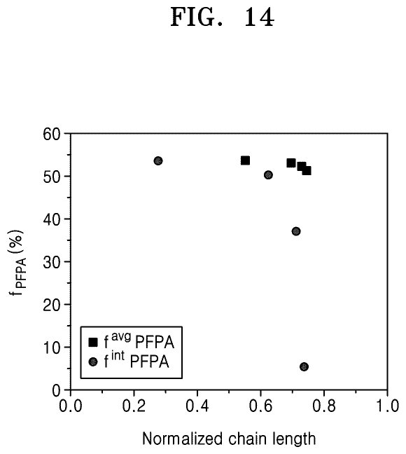

FIG. 14 is a graph illustrating aspects of the volume fraction (f_{PFPA}) of PFPA depending on a normalized polymer chain length, in the block copolymer obtained in Synthesis Example 1. From the result of FIG. 14, it may be confirmed that a concentration gradient of the reactive monomer, PFPA was formed in the block copolymer obtained in Synthesis Example 1.

To check whether the concentration gradient (e.g., gradient copolymer) is formed or not in the evaluation of FIG. 14, the ratio between the PFPA monomer and the styrene monomer in the block copolymer synthesized for each polymerization reaction time was measured. The average volume fraction (f^{avg}_{PFPA}) of the polymer of PFPA in the whole synthesized polymer was measured every 10 minutes, and a change in the average volume fraction (f^{avg}_{PFPA}) was represented by the interval volume fraction (f^{int}_{PFPA}) of the polymer of PFPA.

According to the result of FIG. 14, in all the intervals in which the evaluation was performed, the average volume fraction (f^{avg}_{PFPA}) has no significant difference but tends to decrease a little on the whole. However, in the case of the interval volume fraction (f PFPA), the PFPA monomer is included in the polymer first due to the difference in reactivity, and then, the styrene monomer with a relatively low proportion is included in the polymer. Therefore, when the polymer has a small length (normalized chain length=0.2 to 0.6), the interval volume fraction (f^{int}_{PFPA}) of the PFPA monomer in the interval corresponding thereto is relatively high. On the other hand, as the length of the polymer increases (normalized chain length ≥0.6), the volume fraction of the PFPA monomer in the interval corresponding thereto is significantly reduced. That is, as the PFPA monomer and the styrene monomer are randomly included in the polymer during the polymerization process of the polymer, it may be seen that the polymerization is performed in such a manner that the proportion of the PFPA monomer is high in the initial stage of the polymerization and the styrene monomer is included more in the polymer than the PFPA monomer as the reaction continues to increase the length of the polymer.

### Synthesis Example 2

### Synthesis of block copolymer of Formula 1 (poly(methyl methacrylate)-block-poly(bis(trimethylsilyl)methylamido acrylate-gradient-styrene) (Hereinafter, Referred to as PMMA-b-P(Si₂-g-S))

A synthesis process of PMMA-b-P(Si₂-g-S) is briefly shown in Reaction Formula 3.

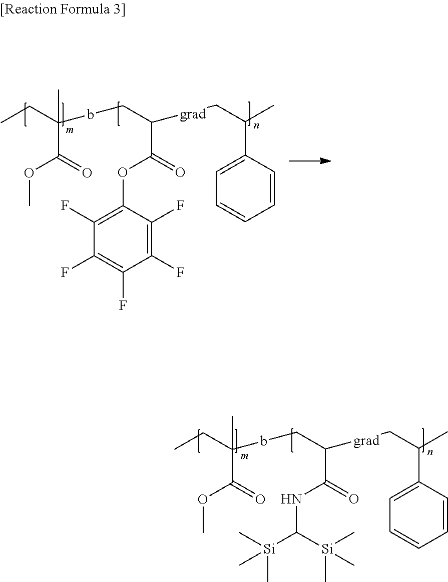

More specifically, to use a concentration gradient in the block copolymer of poly(methyl methacrylate)-block-poly(pentafluorophenyl acrylate-gradient-styrene), which was obtained in Synthesis Example 1, in synthesizing PMMA-b-P(Si₂-g-S), a modification reaction of the block copolymer obtained in Synthesis Example 1 was performed by using bis(trimethylsilyl)methylamine. To this end, the block copolymer obtained in Synthesis Example 1 and bis(trimethylsilyl)methylamine were dissolved with a molar ratio of 1:1.5 in toluene and then underwent a reaction at 50° C. for 5 hours in a nitrogen atmosphere. As a result, the pentafluorophenyl group of the block copolymer obtained in Synthesis Example 1 was substituted by a bis(trimethylsilyl)methylamido group, thereby obtaining, as a resulting product, the block copolymer, poly(methyl methacrylate)-block-poly(bis(trimethylsilyl)methylamido acrylate-gradient-styrene, which is a block copolymer of Formula 1.

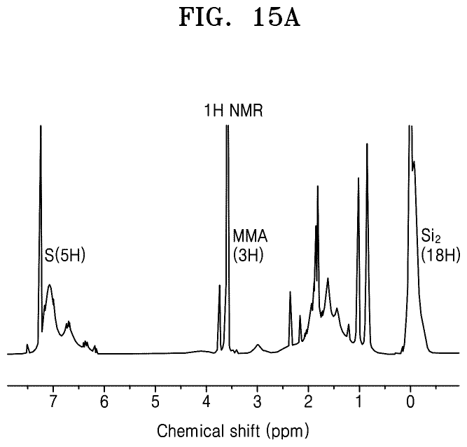

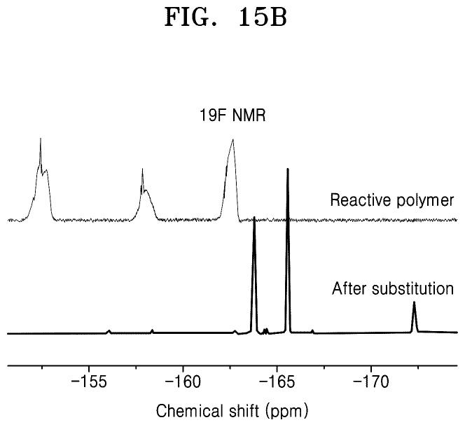

FIGS. 15A and 15B each illustrate aspects of a nuclear magnetic resonance spectrum of the block copolymer of Formula 1, which was obtained in Synthesis Example 2.

From the hydrogen nuclear magnetic resonance spectrum shown in FIG. 15A, it may be confirmed that, after the product according to Synthesis Example 2 is synthesized, the peak of the reactive polymer, poly(pentafluorophenyl methacylate (PPFPA), disappears and only the respective peaks of the polymer of styrene (e.g., S), the polymer of methylmethacrylate (e.g., MMA), and the polymer of poly(bis(trimethylsilyl)methylamido acrylate) (e.g., Si₂) remain. In addition, the substitution ratio at which the pentafluorophenyl group of the block copolymer obtained in Synthesis Example 1 was substituted by the bis(trimethylsilyl)methylamido group may be calculated through the fluorine-19 nuclear magnetic resonance spectrum shown in FIG. 15B. From the fluorine-19 nuclear magnetic resonance spectrum shown in FIG. 15B, it may be confirmed that, after the pentafluorophenyl group is substituted by the bis(trimethylsilyl)methylamido group, all the peaks of the reactive polymer, PPFPA, disappear, and from this, it may be confirmed that the pentafluorophenyl group of the block copolymer obtained in Synthesis Example 1 was 100% substituted by the bis(trimethylsilyl)methylamido group in the process of Synthesis Example 2.

### Evaluation Example 1

### Formation of Pattern by Using Block Copolymer of Formula 1 (1)

A silicon substrate (which hereinafter may be simply referred to as a substrate) not having undergone any surface treatment was prepared, and the block copolymer, PMMA-b-P(Si₂-g-S), synthesized in Synthesis Example 2 was mixed with 2 wt % of propylene glycol monomethyl ether acetate (PGMEA) based on the total weight of the block copolymer, thereby preparing a base solution. After the substrate was cleaned, the base solution was spin-coated on the substrate at 1500 rpm for 30 seconds. A product obtained as a result was annealed in a vacuum furnace at a temperature of 300° C. for 15 minutes, thereby forming a self-assembled layer.

Next, the PMMA block was selectively removed from the obtained self-assembled layer, thereby forming a line pattern comprising the P(Si₂-g-S) block. To selectively remove the PMMA block, a reactive ion etching process using O₂ plasma was performed for 27 seconds.

### Evaluation Example 2

### Formation of Pattern by Using Block Copolymer of Formula 1 (2)

A self-assembled layer was formed under the same conditions as in Evaluation Example 1. However, in the present example, instead of using a silicon substrate not having undergone surface treatment as in Evaluation Example 1, a PMMA brush liner was formed on a silicon substrate, followed by spin-coating the base solution on the PMMA brush liner, and then, a product obtained as a result was annealed under the same conditions as in Evaluation Example 1, thereby forming the self-assembled layer. Next, the PMMA block was selectively removed from the obtained self-assembled layer under the same conditions as in Evaluation Example 1, thereby forming a line pattern comprising the P(Si₂-g-S) block.

### Evaluation Example 3

### Formation of Pattern by Using Block Copolymer of Formula 1 (3)

A self-assembled layer was formed under the same conditions as in Evaluation Example 1. However, in the present example, instead of using a silicon substrate not having undergone surface treatment as in Evaluation Example 1, a PS brush liner was formed on a silicon substrate, followed by spin-coating the base solution on the PS brush liner, and then, a product obtained as a result was annealed under the same conditions as in Evaluation Example 1, thereby forming the self-assembled layer. Next, the PMMA block was selectively removed from the obtained self-assembled layer under the same conditions as in Evaluation Example 1, thereby forming a line pattern comprising the P(Si₂-g-S) block.

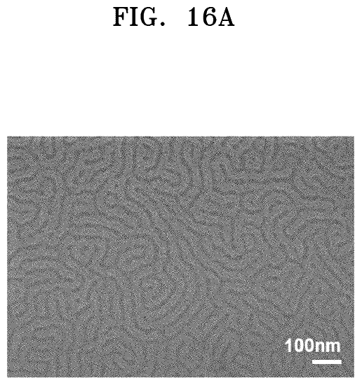

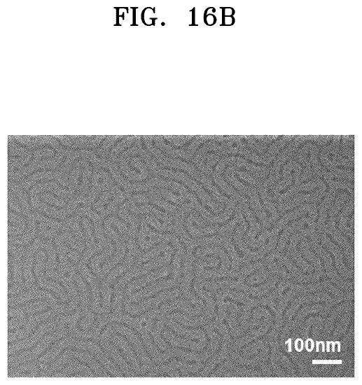

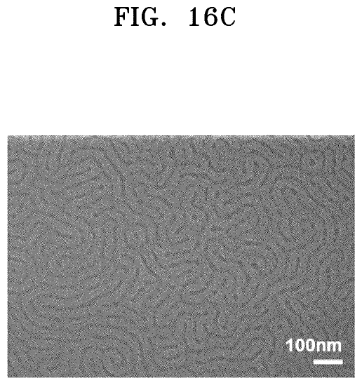

FIG. 16A is a scanning electron microscopic image illustrating aspects of the self-assembled layer obtained in Evaluation Example 1, FIG. 16B is a scanning electron microscopic image illustrating aspects of the self-assembled layer obtained in Evaluation Example 2, and FIG. 16C is a scanning electron microscopic image illustrating aspects of the self-assembled layer obtained in Evaluation Example 3.

As can be seen from the results of FIGS. 16A, 16B, and 16C, when the block copolymer, PMMA-b-P(Si₂-g-S), according to an embodiment has a polymer block comprising a bis(trimethylsilyl)methylamido acrylate repeating unit that has a relatively low surface energy, the patterns in which the PMMA blocks and P(Si₂-g-S) blocks are respectively and vertically aligned are uniformly formed throughout the large area even without forming a brush liner on the surface of the substrate. When used as an etch mask, the P(Si₂-g-S) blocks may provide relatively high etch resistance due to silicon atoms, which are included in the bis(trimethylsilyl)methylamido acrylate repeating unit.

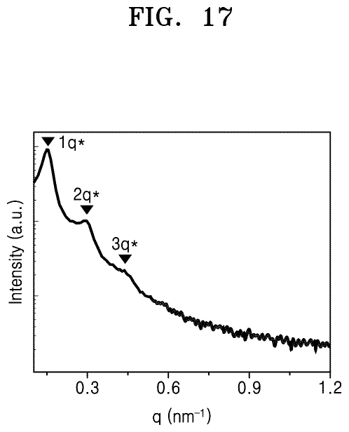

FIG. 17 is a graph illustrating aspects of a result of grazing-incidence small-angle X-ray scattering (GI-SAXS) of the self-assembled layer obtained in Evaluation Example 1. From the result of FIG. 17, it is confirmed that the peaks respectively correspond to 1q*, 2q*, and 3q* and thus to lamellae.

### Synthesis Example 3

### Synthesis of block copolymer of Formula 2 (poly(methyl methacrylate)-block-poly(3-((tributylstannyl)methoxy)-1-propanacetamide)-gradient-styrene) (Hereinafter, Referred to as (PMMA-b-P(SnOA-g-S)

A synthesis process of PMMA-b-P(SnOA-g-S) is briefly shown in Reaction Formula 4.

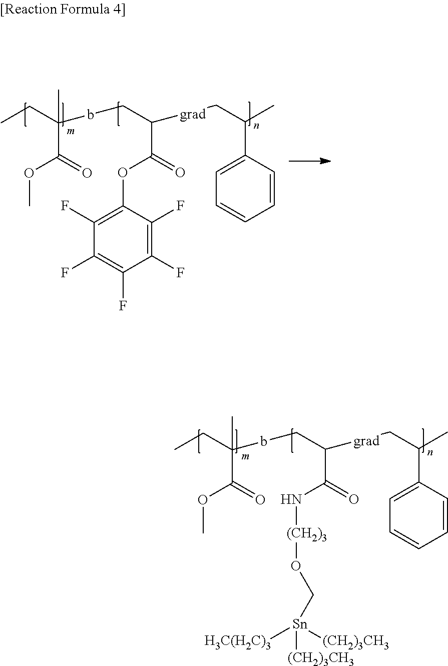

More specifically, to synthesize PMMA-b-P(SnOA-g-S), substantially the same processes as in Synthesis Example 2 were performed. However, 3-[(tributylstannyl)methoxy]-1-propanacetamine was used instead of bis(trimethylsilyl)methylamine. That is, the block copolymer obtained in Synthesis Example 1 and 3-[(tributylstannyl)methoxy]-1-propanacetamine were dissolved with a molar ratio of 1:1.5 in toluene and then underwent a reaction at 50° C. for 5 hours in a nitrogen atmosphere. As a result, the pentafluorophenyl group of the block copolymer obtained in Synthesis Example 1 was substituted by a 3-(tributylstannyl)methoxy group, thereby obtaining, as a resulting product, the block copolymer of Formula 2 (that is, 2(poly(methyl methacrylate)-block-poly(3-((tributylstannyl)methoxy)-1-propanacetamide)-gradient-styrene).

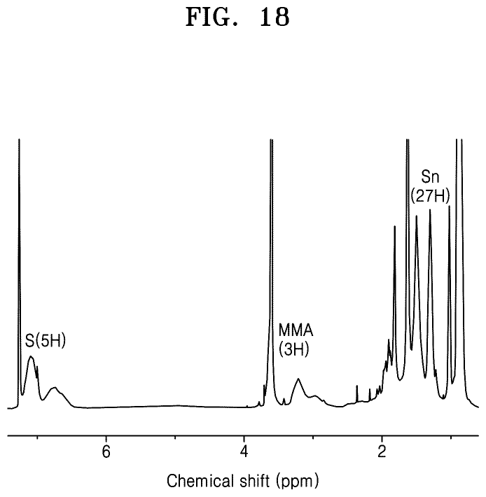

FIG. 18 illustrates aspects of a nuclear magnetic resonance spectrum of the block copolymer of Formula 3, which was obtained in Synthesis Example 3.

### Evaluation Example 4

### Formation of Self-Assembled Layer by Using Block Copolymer of Formula 2

A self-assembled layer, which was obtained from the PMMA-b-P(SnOA-g-S) block copolymer, was formed on a substrate in the same manner as in Evaluation Example 1 except that the PMMA-b-P(SnOA-g-S) block copolymer synthesized in Synthesis Example 4 was used instead of the PMMA-b-P(Si₂-g-S) block copolymer, and then, the PMMA block was selectively removed from the self-assembled layer, thereby forming a line pattern comprising the P(SnOA-g-S) block.

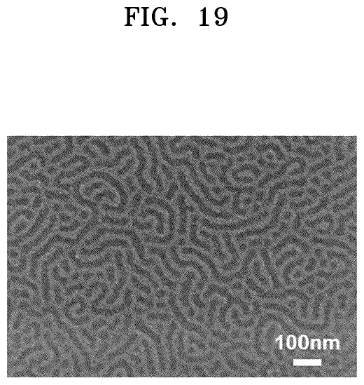

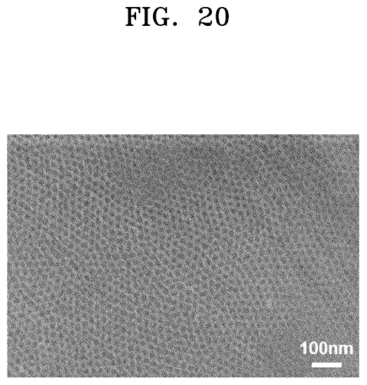

FIGS. 19 and 20 are each a scanning electron microscopic image of the self-assembled layer obtained in Evaluation Example 4.

As can be seen from FIGS. 19 and 20, when the PMMA-b-P(SnOA-g-S) block copolymer according to some embodiments is used, patterns in which the PMMA blocks and P(SnOA-g-S) blocks are respectively and vertically aligned in various shapes are formed even without forming a brush liner on the surface of the substrate. Because the P(SnOA-g-S) blocks each comprise one or more metal atoms, the P(SnOA-g-S) blocks may provide relatively high etch resistance when used as an etch mask.

As described above, a block copolymer according to some embodiments comprises an inorganic material-containing random block in which a unit comprising a pendant group comprising an inorganic material and a unit that is devoid of an inorganic material-containing substituent are connected to each other to provide a concentration gradient (e.g., to form a gradient copolymer). Although comprising an inorganic material having low surface energy, the inorganic material-containing random block, which is included in the block copolymer according to some embodiments, may be vertically aligned even without undergoing a separate surface energy neutralization process, when used to form a pattern of an integrated circuit device. Therefore, when a plurality of patterns, such as a plurality of line patterns or a plurality of hole patterns, are formed by using a self-assembled layer obtained after the phase separation of the block copolymer, the phase separation properties of the block copolymer may improve, thereby improving the LER and the CD uniformity of the plurality of patterns.

While the present invention has been particularly shown and described with reference to embodiments thereof, it will be understood that various changes in form and details may be made therein without departing from the spirit and scope of the following claims.

What is claimed is:

1. A block copolymer comprising a first polymer block and a second polymer block,
wherein the first polymer block and the second polymer block have different structures from each other,
wherein the first polymer block comprises a first unit derived from an acrylic acid ester, and the second polymer block comprises a second unit comprising an inorganic material-containing group and a third unit that is devoid of an inorganic material-containing group, and
wherein the second polymer block comprises an inorganic material-containing random block having a concentration gradient.

2. The block copolymer of claim 1, wherein the inorganic material-containing group comprises a metalloid or a metal.

3. The block copolymer of claim 1, wherein the inorganic material-containing group comprises a Si atom or a Sn atom.

4. The block copolymer of claim 1, wherein the second unit comprises a pendant group according to -M(R)₃, wherein:
M is a metalloid element or a metal element, and
R is a C1 to C10 linear or branched alkyl group.

5. The block copolymer of claim 1, wherein:
the first unit comprises poly(methyl methacrylate) (PMMA),
the second unit comprises an acrylate substituted with the inorganic material-containing group, and
the third unit comprises polystyrene (PS).

6. The block copolymer of claim 1, wherein the block copolymer has a structure according to General Formula 1: 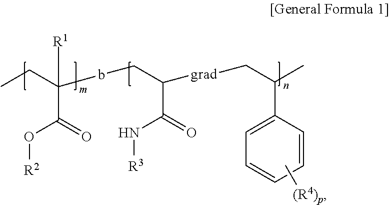
wherein:
R¹ is a hydrogen atom or a methyl group;
R² is a hydrogen atom, a C1 to C10 linear or branched alkyl group, or a C1 to C10 linear or branched alkyl halide group;
R³ is a pendant group comprising the inorganic material-containing group;
each R⁴ is independently a hydrogen atom, a halogen atom, a C1 to C5 linear or branched alkyl group, or a C1 to C5 linear or branched alkyl halide group;
p is an integer of 1 to 5; and
m/(m+n) and n/(m+n) are each independently 0.2 to 0.8.

7. The block copolymer of claim 6, wherein the block copolymer has a structure according to Formula 1: 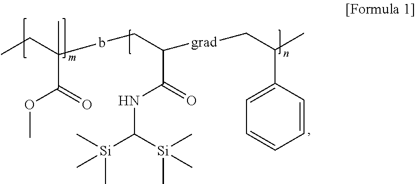
wherein:
m/(m+n) and n/(m+n) are each independently 0.2 to 0.8.

8. The block copolymer of claim 6, wherein the block copolymer has a structure according to Formula 2 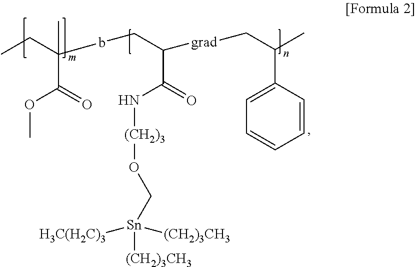
wherein:
m/(m+n) and n/(m+n) are each independently 0.2 to 0.8.

9. A method of manufacturing an integrated circuit device, the method comprising:
forming, on a feature layer, a block copolymer layer comprising a block copolymer, wherein the block copolymer comprises a first polymer block and a second polymer block that have different structures from each other, wherein the first polymer block comprises a first unit derived from an acrylic acid ester, and the second polymer block comprises a second unit comprising an inorganic material-containing group and a third unit that is devoid of an inorganic material-containing group, and
wherein the second polymer block comprises an inorganic material-containing random block having a concentration gradient;
phase-separating the block copolymer layer to form a structure that comprises a plurality of first domains and at least one second domain that comprises the second polymer block, wherein the plurality of first domains each comprise the first polymer block;
removing the plurality of first domains; and
etching the feature layer using the at least one second domain as an etch mask.

10. The method of claim 9, wherein the feature layer comprises an inorganic insulating film or an inorganic conductive film, and,
in the forming of the block copolymer layer, the block copolymer layer directly contacts the feature layer.

11. The method of claim 9, wherein, in the phase-separating of the block copolymer layer, an amount of the second unit in a first portion of the at least one second domain, which is located adjacent to the plurality of first domains, is greater than an amount of the second unit in a second portion of the at least one second domain, which is located farther from the plurality of first domains than the first portion of the at least one second domain.

12. The method of claim 9, wherein, in the forming of the block copolymer layer,
the second unit comprises a pendant group according to -M(R)₃, wherein: M is a metalloid element or a metal element, and R is a C1 to C10 linear or branched alkyl group.

13. The method of claim 9, wherein, in the forming of the block copolymer layer,
the first unit comprises poly(methyl methacrylate) (PMMA),
the second unit comprises an acrylate comprising a pendant group that comprises a Si atom or an Sn atom, and
the third unit comprises polystyrene (PS).

14. The method of claim 9, wherein, in the forming of the block copolymer layer, the block copolymer has a structure according to General Formula 1: 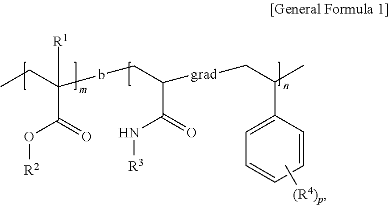
wherein:
R¹ is a hydrogen atom or a methyl group;
R² is a hydrogen atom, a C1 to C10 linear or branched alkyl group, or a C1 to C10 linear or branched alkyl halide group;
R³ is a pendant group comprising the inorganic material-containing group;
each R⁴ is independently a hydrogen atom, a halogen atom, a C1 to C5 linear or branched alkyl group, or a C1 to C5 linear or branched alkyl halide group;
p is an integer of 1 to 5; and
m/(m+n) and n/(m+n) are each independently 0.2 to 0.8.

15. The method of claim 9, wherein, in the forming of the block copolymer layer, the block copolymer has a structure according to Formula 1: 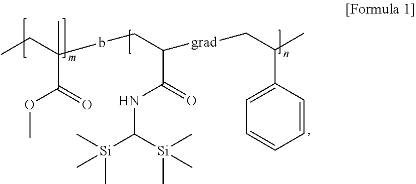
wherein:
m/(m+n) and n/(m+n) are each independently 0.2 to 0.8.

16. The method of claim 9, wherein, in the forming of the block copolymer layer, the block copolymer has a structure according to Formula 2: 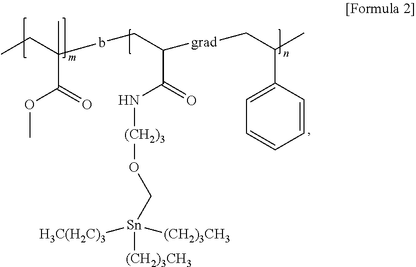
wherein:
m/(m+n) and n/(m+n) are each independently 0.2 to 0.8.

17. A method of manufacturing an integrated circuit device, the method comprising:
forming, on a feature layer, a block copolymer layer comprising a block copolymer,
wherein the block copolymer comprises a first polymer block and a second polymer block that have different structures from each other, wherein the first polymer block comprises a first unit derived from an acrylic acid ester, and the second polymer block comprises a second unit and a third unit, wherein the second unit comprises a pendant group comprising a structure according to
-M(R)₃, wherein M is a metalloid element or a metal element and R is a C1 to C10 linear or branched alkyl group, wherein the third unit is devoid of an inorganic material-containing group, and wherein the second polymer block comprises an inorganic material-containing random block having a concentration gradient;
phase-separating the block copolymer layer to form a structure that comprises a plurality of first domains and at least one second domain that comprises the second polymer block,
wherein the plurality of first domains each comprise the first polymer block, and wherein the at least one second domain has a concentration gradient of the pendant group, which comprises the inorganic material, and the concentration gradient is over a distance extending from each of the plurality of first domains;
removing the plurality of first domains; and
etching the feature layer using the at least one second domain as an etch mask.

18. The method of claim 17, wherein the feature layer comprises an inorganic insulating film or an inorganic conductive film, and,
in the forming of the block copolymer layer, the block copolymer layer directly contacts the feature layer.

19. The method of claim 17, wherein, in the forming of the block copolymer layer, the block copolymer has a structure according to General Formula 1: 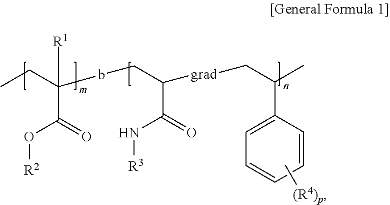
wherein:
R¹ is a hydrogen atom or a methyl group;
R² is a hydrogen atom, a C1 to C10 linear or branched alkyl group, or a C1 to C10 linear or branched alkyl halide group;
R³ is the pendant group comprising the inorganic material-containing group;
each R⁴ is independently a hydrogen atom, a halogen atom, a C1 to C5 linear or branched alkyl group, or a C1 to C5 linear or branched alkyl halide group;
p is an integer of 1 to 5; and
m/(m+n) and n/(m+n) are each independently 0.2 to 0.8.

20. The method of claim 17, wherein, in the forming of the block copolymer layer, the block copolymer has a structure according to Formula 1 or Formula 2: 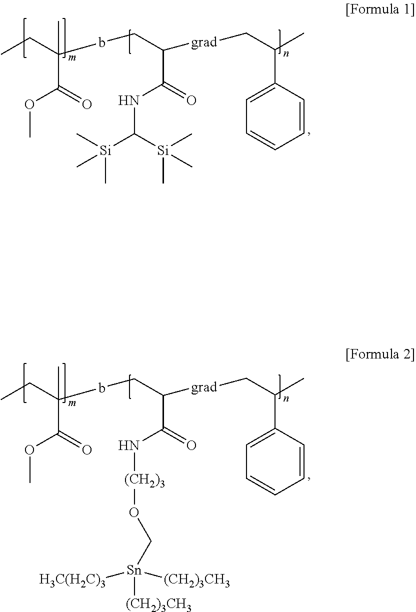
wherein m/(m+n) and n/(m+n) are each independently 0.2 to 0.8.
